(19) United States
(12) Patent Application Publication
(10) Pub. No.: US 2013/0045604 A1
(43) Pub. Date: Feb. 21, 2013

(54) PLASMA PROCESSING APPARATUS AND PLASMA PROCESSING METHOD

(71) Applicants: Kenji MAEDA, Kodaira (JP); Atsushi Itou, Kudamatsu (JP); Masaru Izawa, Hino (JP)

(72) Inventors: Kenji MAEDA, Kodaira (JP); Atsushi Itou, Kudamatsu (JP); Masaru Izawa, Hino (JP)

(21) Appl. No.: 13/235,666

(22) Filed: Sep. 19, 2011

(30) Foreign Application Priority Data
Aug. 15, 2011 (JP) 2011-177387

(51) Int. Cl. H01L 21/3065; C23F 1/08

(52) U.S. Cl. 438/710; 156/345.28; 257/E21.218

(57) ABSTRACT

A plasma processing apparatus which can adjust ion energy on a wafer to a value in a desired range to perform machining with high precision or processing stably for a long time is provided. To the plasma processing apparatus which processes a wafer mounted on a mounting surface of an upper portion of a stage using plasma formed in a processing chamber while supplying radio frequency power from a power supply to an electrode disposed in the stage a detector disposed on an outer circumferential side of the mounting surface of the stage to detect a differential component Vpp between the maximum value and the minimum value and a DC component Vdc from a value of a bias voltage formed thereabove and a controller to adjust an output of the radio frequency bias power to make a value of Vpp/2+|Vdc| constant based on an output from the detector are provided.

### BACKGROUND OF THE INVENTION

The present invention relates to a plasma processing apparatus and a plasma processing method for processing a substrate-like sample such as a semiconductor wafer disposed in a processing chamber in a vacuum vessel using plasma formed in the processing chamber. Particularly, it relates to a plasma processing apparatus and a plasma processing method in which a bias potential based on radio frequency power is formed on a sample mounted on a mounting surface of a sample stage in a processing chamber during processing so as to process the sample.

In a mass production process of semiconductor devices, plasma processing such as plasma etching, plasma CVD (Chemical Vapor Deposition), or plasma ashing has broadly been used. Plasma processing is performed by supplying radio frequency power or microwave power to process gas which has been decompressed so that plasma is generated and a wafer is irradiated with ions or radicals. Particularly in plasma etching, a radio frequency bias of several hundreds of kHz or several tens of MHz is supplied to a wafer to bring ions in plasma to the wafer aggressively and, thus, to perform highly anisotropic machining.

In addition, according to ITRS (International Technology Roadmap for Semiconductors), it is expected that miniaturization of semiconductor devices will progress in the future and that 22 nm node mass production will start in 2014 to 2016. It is also expected that the mainstream of transistor structures at that time will be shifted from a planar type which is the mainstream now to a FinFET type having a 3D structure, such as a double-gate type or a tri-gate type. Extreme micro-machining performance, controllability, and stability are required in a plasma processing apparatus for use in the production of such future semiconductor devices, particularly in a plasma etching apparatus which is essential for miniaturization.

In order to obtain desired performance as to an etch profile, an etching rate, mask selectivity, substrate selectivity, and the like, processing in a plasma etching apparatus is generally performed as parameters (external parameters) such as source power for generating plasma, bias power, flow rates of various gases, and gas pressures, are adjusted in ranges of desired values. On the other hand, investigation has not been made thoroughly on an idea to perform processing as parameters (internal parameters) such as values of plasma density and radical density, distributions thereof, and energy of ions incident on a wafer, which are related directly to the etching performance, are detected and adjusted in ranges of desired values.

As an example of prior art, JP-A-2000-269195 discloses a technology in which at least one of a peak-to-peak value Vpp of a bias voltage, a self-bias voltage Vdc, and impedance Z of an apparatus system is measured at a point between an exit of a matching box for wafer bias and an electrode for retaining a wafer so as to control the output of a bias power supply based on the measured value. According to JP-A-2000-269195, bias power, which is an external parameter, is not controlled to be constant but is controlled with feedback to make Vpp, Vdc, and the like of the bias voltages constant so that stable operation of an etching apparatus for a long time, that is suppression of change with age in the etching characteristics during long-term operation, is enabled; further, proper time for cleaning of a plasma processing chamber can be determined.

Also, JP-A-2005-277270 discloses a technology in which wafer bias Vpp is kept at a desired constant value by a step of measuring the wafer bias Vpp during plasma processing and a step of adjusting capacitance between a wafer retaining electrode and a radio frequency bias power supply. With such a configuration according to the prior art, variation in the condition of plasma is reduced and equalized for each wafer so that unevenness of processing can be reduced.

Further, as a method for etching a film structure with steps such as a FinFET with high precision, JP-A-2008-244429 discloses a technology in which bias power of plural frequencies is supplied to a wafer to independently control average energy of ions incident on the wafer and their ion energy distribution function (IEDF). Furthermore, JP-A-10-074481 discloses a method for measuring ion energy on a measurement object to which radio frequency power is applied.

### SUMMARY OF THE INVENTION

In order to cope with miniaturization of devices in the future, it is essential in respective etching conditions to control ion energy distributions corresponding to required processing specifications. For such a task, there arise problems because investigations are insufficient in point of the followings in the aforementioned prior arts.

For example, in the technology disclosed in JP-A-2008-244429 it is not taken into consideration that, because the conditions of walls of an etching chamber or the vapor-phase atmosphere change momentarily during actual etching and the ion energy distributions also change with time accordingly, supplying bias power of plural frequencies matched for such changes to a wafer or an electrode in a sample stage is difficult. Further, even when the ion energy distribution is detected and the output of a wafer bias power supply is intended to be adjusted accordingly using the technology disclosed in JP-A-10-074481, the structure for monitoring the ion energy distribution is so complicated in principle that it costs very much and it is therefore difficult to provide an apparatus for manufacturing semiconductor devices for industry.

Besides, in the technology disclosed in JP-A-2000-269195 or JP-A-2005-277270, the bias voltage on the electrode retaining a wafer, that is the bias Vpp or Vdc, is measured, and the output of the bias power supply or the capacitance is controlled to keep it constant. According to investigations by the present inventors, however, a finding has been obtained that the distribution of ion energy on an upper surface of the wafer cannot be always kept constant only by adjustment of keeping Vpp or Vdc constant.

Using FIGS. 5A and 5B a relation between a waveform of a bias voltage and IEDF on a wafer is schematically shown. FIGS. 5A and 5B are graphs schematically showing a waveform of a bias voltage on a surface of a wafer of an arbitrary shape and an ion energy distribution function.

As shown in FIG. 5A, a waveform of a bias voltage due to radio frequency power supplied to an electrode in a sample stage typically has a form roughly sinusoidal. Also, the mobility of electrons is overwhelmingly higher than that of positive ions and a negative self-bias voltage Vdc is generated.

On the other hand, the energy distribution of ions in plasma, which are accelerated by a bias voltage with such a waveform and injected on a wafer, generally has a shape with plural (two in this example) peaks as shown as IEDF in FIG. 5B. As a result of investigations by the present inventors, a finding has been obtained that, in case of etching, a high-energy peak of the IEDF shown in FIG. 5B has the greatest influence on properties such as the perpendicularity of a pattern and selectivity to a substrate.

Also, as understood from FIG. 5B, the value of a high-energy peak and the ion energy value corresponding thereto depend on the value of Vpp/2+|Vdc| and it is, therefore, difficult in the aforementioned prior art to obtain sufficiently high processing and machining precision by adjusting the ion energy. Particularly, it is not taken into consideration in the prior art that, because the conditions of walls of an etching chamber or the vapor-phase atmosphere change momentarily during actual etching, a certain correlation may not necessarily exist between Vpp and Vdc all the time during the processing, it is difficult to obtain a desired ion energy distribution only by adjustment of keeping Vpp or Vdc constant.

Further, Vpp is indeed measured on a wafer in prior art, but it is very difficult to actually measure Vdc on the wafer. Because a current etching processing apparatus or a plasma processing apparatus generally uses an electrostatic chuck for making a wafer electrostatically adhere to thereby retain it on an electrode and in an apparatus provided with such an electrostatic chuck and a self-bias voltage Vdc generated on the wafer is blocked by an insulating film on the electrostatic chuck, it is difficult to measure the Vdc even if a unit for measuring the Vdc is provided between an exit of a matching box for a bias and an electrode for retaining the wafer as described in JP-A-2000-269195.

An objective of the present invention is to provide a plasma processing apparatus which can adjust ion energy on a wafer to a value in a desired range to perform machining with high precision or processing stably for a long time by solving the foregoing problems.

An objective of the present invention is attained by comprising a unit which can detect Vdc generated on a wafer in a processing chamber in a simple manner and adjusting the value of Vpp/2+|Vdc| within a predetermined range so as to reduce a fluctuation of energy peaks of IEDF. More particularly, it is attained in a plasma processing apparatus which comprises: a vacuum processing chamber which is evacuated by an vacuum pumping unit; a gas supply unit which supplies gas to the vacuum processing chamber; a source power supply which turns the gas into plasma; a substrate stage on which a wafer is mounted; a radio frequency bias power supply which applies radio frequency bias power to the wafer through the substrate stage; by a plasma processing apparatus which is characterized by comprising a conductor member which is capacitively coupled with a base portion of the substrate stage and directly touches the plasma, a surface of the conductor member being located at substantially the same height as the wafer and outside an outermost circumferential portion of the wafer; and a unit which detects a peak-to-peak component Vpp and a DC component Vdc of a waveform of a bias voltage generated on the conductor member; wherein an output of the radio frequency bias power is controlled with feedback to keep a value of Vpp/2+|Vdc| constant during plasma processing.

Other objects, features, and advantages of the invention will become apparent from the following description of the embodiments of the invention taken in conjunction with the accompanying drawings.

### BRIEF DESCRIPTION OF THE DRAWINGS

FIG. 1 is a longitudinal sectional view showing an outline of a configuration of a plasma processing apparatus according to an embodiment of the present invention;

FIG. 2 is a longitudinal sectional view showing an outline of a configuration of a voltage detection head according to the embodiment shown in FIG. 1;

FIG. 3 is a perspective view schematically showing an outline of a configuration of a voltage detection portion shown in FIG. 2;

FIG. 4 is a plan view from above of an appearance in which the voltage detection head shown in FIG. 2 is disposed inside a susceptor; and

FIGS. 5A and 5B are graphs schematically showing a waveform of a bias voltage and an ion energy distribution function on a surface of a wafer of an arbitrary shape.

### DESCRIPTION OF THE EMBODIMENTS

An embodiment of a plasma processing apparatus according to the present invention is now described below using the drawings.

### Embodiment

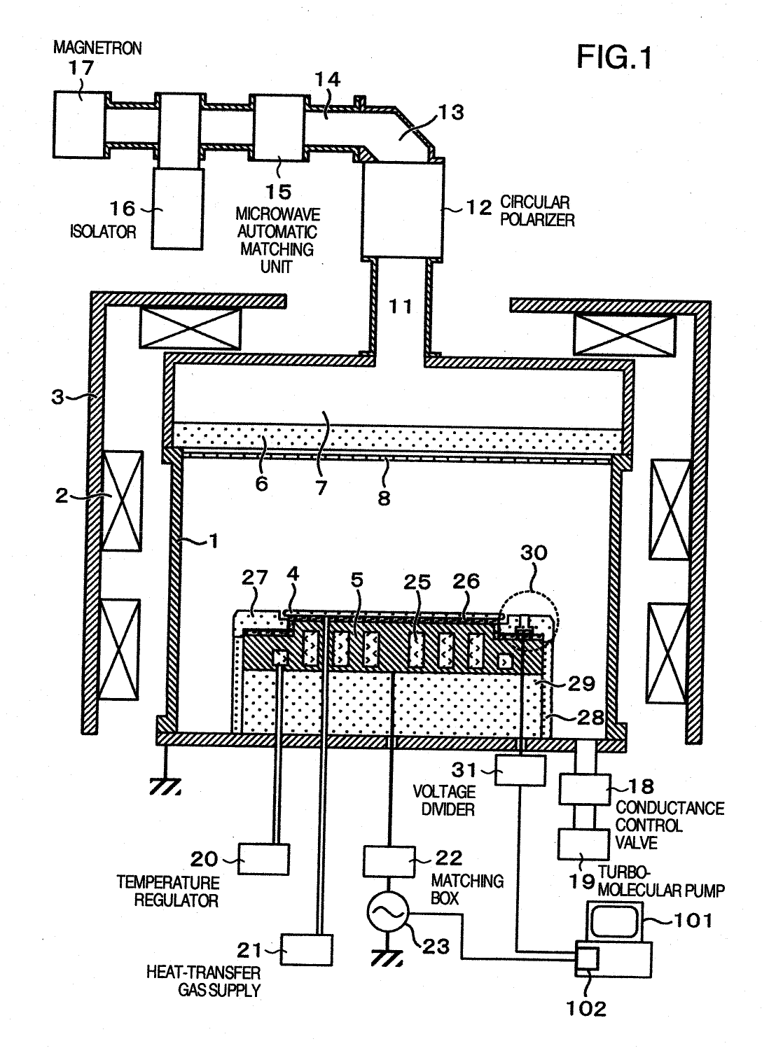

An embodiment of the present invention is described using FIGS. 1 to 4.

FIG. 1 is a longitudinal sectional view showing an outline of a configuration of a plasma processing apparatus according to an embodiment of the present invention. The plasma processing apparatus according to the embodiment includes a vacuum vessel; an electromagnetic field supply unit for supplying an electric field or a magnetic field for forming plasma in a vacuum processing chamber 1 disposed in the vacuum vessel is disposed above the vacuum vessel and an evacuation unit for evacuating the vacuum processing chamber 1 is disposed under the vacuum vessel. In addition, the vacuum processing chamber 1 in the vacuum vessel has a substantially cylindrical shape and a substrate stage 5, on a top surface of which a wafer 4 is mounted and retained as on a mounting surface, is provided in the vacuum vessel under the vacuum processing chamber 1.

The evacuation unit is connected to an exhaust port disposed under the vacuum processing chamber 1; the vacuum processing chamber communicates with an inlet of a vacuum pump such as a turbo-molecular pump 19 through a passageway. A conductance control valve 18 which can rotate to adjust the cross-sectional area of a flow channel in the exhaust passageway variably is disposed between the vacuum pump and the exhaust port so that an amount of evacuation and rate in the vacuum processing chamber 1 are controlled by adjustments of the operation of the evacuation pump and of the cross-sectional area of the flow channel with the conductance control value 18.

A space for forming plasma is disposed above the substrate stage 5 of the vacuum processing chamber 1 and at its ceiling surface a microwave transmitting window 6 of a disc shape and made of a dielectric material such as quartz is provided. A cylindrical cavity 7 is provided above the microwave transmitting window 6 so that a top surface of the microwave transmitting window 6 constitutes a bottom surface of the cylindrical cavity 7. An electric field (electric field of microwaves in this embodiment) for forming plasma is supplied to the cylindrical cavity 7 from above and the height of the cylindrical cavity 7 is adjusted so that a microwave of a circular TE01 mode resonates in the cylindrical cavity.

A shower plate 8 is provided at a position to face to the substrate stage 5 below the microwave transmitting window 6 with a gap therefrom. The gap with the microwave transmitting window 6 is connected to a not-shown gas supply channel which is connected to a gas supply outside the vacuum processing chamber 1; after gas from the gas supply is introduced into the gap and diffused therein, gas for processing is introduced as being diffused into the vacuum processing chamber 1 via through holes, which are disposed in an area facing to the substrate stage 5 in a central portion of the shower plate 8.

A circular waveguide 11 is connected to the ceiling surface comprising a ring-like plate disposed in an upper portion of the cylindrical cavity 7 and a microwave propagated through the circular waveguide 11 is introduced into the cylindrical cavity 7. In this embodiment, for example, an industrial frequency of 2.45 GHz is used as the frequency of the microwave. The electric field of the microwave propagated through the circular waveguide 11 is resonated in a predetermined mode in the cylindrical cavity 7, transmitted through the microwave transmitting window 6 and the shower plate 8 below, and supplied into the vacuum processing chamber 1 further below.

Further, outside the vacuum processing chamber 1 and surrounding an upper portion of the cylindrical cavity 7 and a lateral outer circumference of the vacuum processing chamber 1 or the cylindrical cavity 7 a magnetic field forming unit is provided, which comprises one to three systems of solenoid coils 2 and a yoke 3. DC power is supplied to each solenoid coil 2 during processing of the wafer 4 so as to supply a generated magnetic field into the vacuum processing chamber 1.

As processing of the wafer 4, the wafer 4 having a substantially disc-like shape is transferred into the vacuum processing chamber 1 through a gate having an opening disposed on the vacuum vessel, delivered to the substrate stage 5, mounted on its substrate mounting surface which has a circular shape, and adhered and retained thereon electrostatically. In this state, while being evacuated through the exhaust port by the operation of the vacuum pump and the conductance control valve 18, the process gas is introduced into the vacuum processing chamber 1 through the shower plate 8 so that the pressure in the vacuum processing chamber 1 is adjusted to a desired value by the balance of flow rates between the evacuation and the introduction of the process gas introduced through the shower plate 8. In this embodiment, it is configured so that the pressure can be adjusted in a range of from 0.05 Pa to 10 Pa in accordance with the process conditions of the wafer 4.

The electric field of the microwave transmitted through the microwave transmitting window 6 and the shower plate 8 is supplied into the vacuum processing chamber 1 and a magnetic field is supplied from the magnetic field supply unit. As a result of interaction of the electric field and the magnetic field, the process gas is excited and turned into plasma. On this occasion, a magnetic field of 875 Gauss which is the intensity to induce ECR resonance is supplied inside the vacuum processing chamber 1 by the solenoid coils 2 so that stable plasma can be generated at a pressure of from about 0.05 Pa to about 5 Pa.

An electrode made of metal is disposed in the substrate stage 5 and a unit for applying radio frequency bias power to the electrode to thereby form a radio frequency bias potential above the wafer 4 mounted on the top surface of the substrate stage 5 is provided. Due to potential difference between the radio frequency bias potential and the plasma, ions in the plasma are brought into the wafer to enhance etching process. In this embodiment, the substrate stage 5 is further provided with a voltage detection head 30 for accurately detecting the waveform of the radio frequency bias voltage, which is connected to a voltage divider 31.

The vacuum vessel constituting the vacuum processing chamber 1 is made of metal such as aluminum and electrically grounded. In addition, a portion forming an inner wall of the vacuum processing chamber 1 is coated with a film which is about 50 μm to 500 μm thick made of an insulating material which has resistance against plasma and less likely to give metal contamination to devices, that is ceramics such as yttria (Y₂O₃), alumina (Al₂O₃), yttrium fluoride (Y₂F₃), aluminum fluoride (Al₂F₃), aluminum nitride (AlN) or quartz (SiO₂), or a compound of those.

Also, by adopting a structure which can control temperature of the vacuum processing chamber 1, processing stability in mass production can be improved. Control of the temperature of the vacuum processing chamber 1 can be realized by forming a flow channel, in which liquid can flow, inside a side wall of the vacuum processing chamber 1 in advance and making liquid whose temperature is controlled by a chiller or the like flow into the flow channel. Alternatively, a heater may be provided on an atmosphere side of the vacuum processing chamber 1. The temperature of the vacuum processing chamber 1 is adjusted to a desired temperature from 30° C. to 100° C. with such a temperature control unit. Also, by embedding a temperature monitoring unit such as a platinum thermometer in a metal wall portion of the vacuum processing chamber 1 and controlling with feedback the temperature of the vacuum processing chamber, further stabilization of processes can be expected.

The diameter of the microwave transmitting window 6 having a disc-like shape is slightly larger than the inner diameter of the vacuum processing chamber 1 and the outer circumferential portion is sealed with an O-ring or the like so that the inside of the vacuum processing chamber 1 is sealed off air-tightly from external air of the atmospheric pressure in the outside. A material which is low in loss of microwave and does not cause contamination, such as quartz, alumina, or yttria is preferable as the material of the microwave transmitting window 6.

As the material of the shower plate 8 which is disposed under the microwave transmitting window 6, made of a dielectric, and formed into a substantially disc-like shape, a material which is low in loss of microwaves and does not cause contamination, such as quartz, alumina, or yttria is preferable similar to the material of the microwave transmitting window 6. Through holes of diameters of about 0.1 mm to about 0.8 mm are formed at a pitch of about 5 mm to about 20 mm in the shower plate 8 and, in addition, its thickness is set properly in a range of from 5 mm to 15 mm.

A gap of about 0.1 mm to 1 mm is formed between the shower plate 8 and the microwave transmitting window 6 and serves as a gas buffer chamber in which process gas is supplied and diffused; the process gas introduced from an outer circumferential portion of the gas buffer chamber is diffused and unevenness in flow rate at which the process gas flows into the vacuum processing chamber 1 through the through holes is suppressed as a result. Moreover, by dividing the gas buffer chamber and the shower plate 8 into two regions of an inner circumferential portion and an outer circumferential portion and connecting different gas supply systems (not shown) to respective regions to properly adjust species, compositions, and flow rates of process gases flowing into the inner circumferential portion and the outer circumferential portion, the distributions of radical species reaching the wafer can be controlled.

Thus, higher processing uniformity in the surface of the wafer can be achieved. Incidentally, as the process gases, one to about four species of reactive gases such as Cl₂, HBr, HCl, CF₄, CHF₃, SF₆, BCl₃, O₂, and CH₄ are selected suitably in accordance with the kind of the film to be etched and the respective flow rates and the mixture ratio thereof are properly adjusted. Also, diluent gas such as Ar or Xe may be added to the mixture of reactive gases at a suitable flow rate.

The bottom surface of the cylindrical cavity portion 7 is constituted by the top surface of the microwave transmitting window 6 and the ceiling surface is constituted by a ring-like metal disc. A circular waveguide 11 is connected to its central portion to form a microwave supply path. In the microwave supply path, the circular waveguide 11, a circular polarizer 12, and a rectangular/circular waveguide conversion portion 13 which have axes in a vertical orientation, and a rectangular waveguide 14, a microwave automatic matching unit 15, an isolator 16, and a magnetron 17 which have axes in a horizontal orientation are disposed along the path of the waveguide axis orientation from the downstream to the upstream of the path.

An electric field by a microwave of a predetermined frequency generated by the magnetron 17 is propagated in a rectangular TE10 mode to the rectangular waveguide through the microwave automatic matching unit 15, converted into a circular TE11 mode by the rectangular/circular waveguide conversion portion 13, and introduced into the cylindrical cavity 7 through the circular polarizer 12. The circular polarizer 12 rotates the plane of polarization of the circular TE11 mode to generate a right-handed circular polarized wave to make the distribution of the electric field uniform circumferentially. In addition, by matching with a load by the microwave automatic matching unit 15 the power of the microwave can be supplied to the plasma load efficiently while reflected power is suppressed. Further, the isolator 16 prevents reflected waves, which can not be eliminated completely by the microwave automatic matching unit 15, from returning to the magnetron.

One to three systems of solenoid coils 2 and a yoke 3 are provided outside the vacuum processing chamber 1. In the embodiment, there is provided a not-shown configuration to adjust a height of an ECR plane (a plane of an equi-magnetic field of 875 Gauss), the shape of the ECR plane, the degree of divergence of magnetic field lines, and the like by properly controlling a DC current flowing in solenoid coils 2. Also, by use of ECR resonance, plasma stable in a low pressure region of from about 0.05 Pa to about 5 Pa, which is advantageous in micro-machining, can be generated and the height of the ECR, the shape of the ECR plane, and the degree of divergence of the magnetic field lines can be controlled to adjust the distribution of plasma density to a desired one.

Toward the bottom of the vacuum processing chamber 1 the substrate stage 5 for mounting the wafer 4 thereon is provided. The base of the substrate stage 5 is made of metal such as aluminum or titanium and isolated by an insulating material 29 from a lower portion member which forms the bottom portion of the vacuum vessel.

An electrode electrically connected to a radio frequency bias power supply 23 via a matching box 22 is disposed in the substrate stage 5 and it corresponds to the base in this embodiment. An insulating film layer 26 of about 200 μm to about 2,000 μM thickness is disposed on a top surface of the base and radio frequency power is supplied in the state that the wafer 4 is mounted on the circular mounting surface of the top surface of the base so that a radio frequency bias potential is formed in the wafer 4. The frequency of the power of the radio frequency bias power supply 23 is selected suitably in a range of from 200 kHz to 13.56 MHz.

In addition, on the outer circumferential side of the mounting surface of the substrate stage 5 a ring-like step portion which is made lower than the height of a top surface of the insulating film layer 26 on the mounting surface is arranged and a susceptor 27 which is a substantially annular member made of a dielectric material such as ceramics is disposed over the portion covered with the insulating film layer 26 of the step portion so that the substrate stage 5 is covered from plasma formed in the vacuum processing chamber 1. Also, the side wall portion of the substrate stage 5 is covered with a substantially cylindrical electrode cover 28 made of a dielectric material. Incidentally, it is preferable that materials of the susceptor 27 and the electrode cover 28 are materials which are high in resistance against plasma and less likely to cause contamination, that is to say materials such as quartz, high-purity alumina, and yttria.

Material of the aforementioned insulating film layer 26 is Al₂O₃, Y₂O₃, AlN, or Al₂O₃ containing about 10% Ti₂O₃ and it is formed by spraying or bonding sintered compact to the top surface of the base. Also, plural film-like electrodes are arranged inside the insulating film layer 26 and a DC voltage source is electrically connected thereto. By applying DC power of several hundreds to several thousands of V when the wafer 4 is mounted on the top surface of the insulating film layer 26 on the mounting surface the wafer 4 is electrostatically adhered to the top portion of the insulating film layer 26.

Further, inside the disc-like or cylinder-like base of the substrate stage 5 coolant channels 25 are arranged through which a coolant flows in order to adjust the temperature of the base and which are arranged in a shape of a spiral or concentric plural arcs at different radial positions. The coolant channels 25 are connected by a duct to a temperature regulator 20 such as a chiller, which is disposed outside the vacuum processing chamber 1, so that the coolant temperature of which is adjusted to a predetermined temperature in the temperature regulator 20 circulates through the coolant channels 25. Due to the circulation of the coolant, the temperature of the substrate stage 5 can be kept in a range of desired values suitable for processing.

Further, in the state where the wafer 4 is mounted and retained on the insulating film layer 26 of the mounting surface, heat-transfer gas such as He is introduced from a heat-transfer gas supply 21 into a gap between the top surface of the insulating layer 26 and a back surface of the wafer 4 through a channel communicating with the opening arranged in its top surface. With the heat-transfer gas heat transfer is enhanced between the wafer 4 and the substrate stage 5 or the base thereof temperature of which is adjusted so that the temperature of the wafer 4 is maintained within a range of desired values suitable for processing.

In the current embodiment, the voltage detection head 30, which detects a peak-to-peak (difference between the maximum value and the minimum value) value Vpp of the bias voltage and a value of the self-bias voltage Vdc generated above the susceptor 27 or the wafer 4 when the radio frequency bias is applied thereto, is disposed inside the susceptor 27 mounted on the step portion arranged in the outer circumference of the mounting surface of the substrate stage 5. The voltage detection head 30 is disposed in the opening which is disposed in a top surface of the susceptor 27 to face the plasma formed in the vacuum processing chamber 1 above; its top surface is held in the same position as the top surface of the susceptor 27 and disposed to be at substantially the same height as the top surface of the insulating film layer 26 on the mounting surface of the substrate stage 5 or the top surface of the wafer 4 mounted thereon.

The voltage detection head 30 in the current embodiment is disposed above the ring-like step portion which is the outer circumferential portion of the mounting surface of the base serving as an electrode and a bias potential due to radio frequency power supplied to the base is formed above, in the same manner as for the wafer 4. Further, the voltage detection head 30 is electrically connected to the input side of the voltage divider 31 provided outside the vacuum processing chamber 1 and directly under the substrate stage 5. Preferably, in order to make measurement without disturbing the waveform of the radio frequency bias voltage or the DC voltage generated at the voltage detection head 30, the input impedance of the voltage divider 31 is 1 MΩ or more and the input capacitance thereof is 50 pF or less.

The waveform of the bias voltage generated on the voltage detection head 30 is supplied to the voltage divider 31, attenuated to about 1/100, and then, outputted to an AD board 102 which is one of input/output interfaces of a control PC 101 disposed outside the vacuum processing chamber 1. The control PC 101 computes the voltage waveform from an inputted signal using an internal computing unit to thereby extract a Vpp component and a Vdc component of the voltage waveform.

Further, based on software or data stored in a storage unit either internal or able to communicate via a communication unit, the control PC 101 detects an output value of the radio frequency bias power supply 23 which makes a value of Vpp/2+|Vdc| constant during etching using a computing unit and sends a command to the radio frequency bias power supply 23 in order to output the value. The control PC 101, which serves as a control portion in the present embodiment, is connected being able to communicate to respective operating portions such as the electromagnetic field supply unit, the evacuation unit, the substrate stage 5, the temperature regulator 20, and the voltage divider 31 and a detection unit such as a sensor in the plasma processing apparatus according to the present embodiment via a communication unit, which is not shown, and to the AD board 102 to adjust the operation of the plasma processing apparatus by sending commands of suitable operations to the respective operating portions based on the operating conditions of the plasma processing apparatus detected by the computing unit from received signals from the detection unit.

As stated previously, since a high-energy peak component of ion energy distribution IEDF incident on a wafer can be estimated by Vpp/2+|Vdc|, even when etching proceeds and the conditions of the walls of the chamber or the atmosphere change, the aforementioned control can prevent the high-energy peak component of IDEF from changing. Thus, the high-energy peak of IDEF can be controlled to be constant in time and high precision machining and long term stability in accordance with miniaturization of the next generation can be implemented.

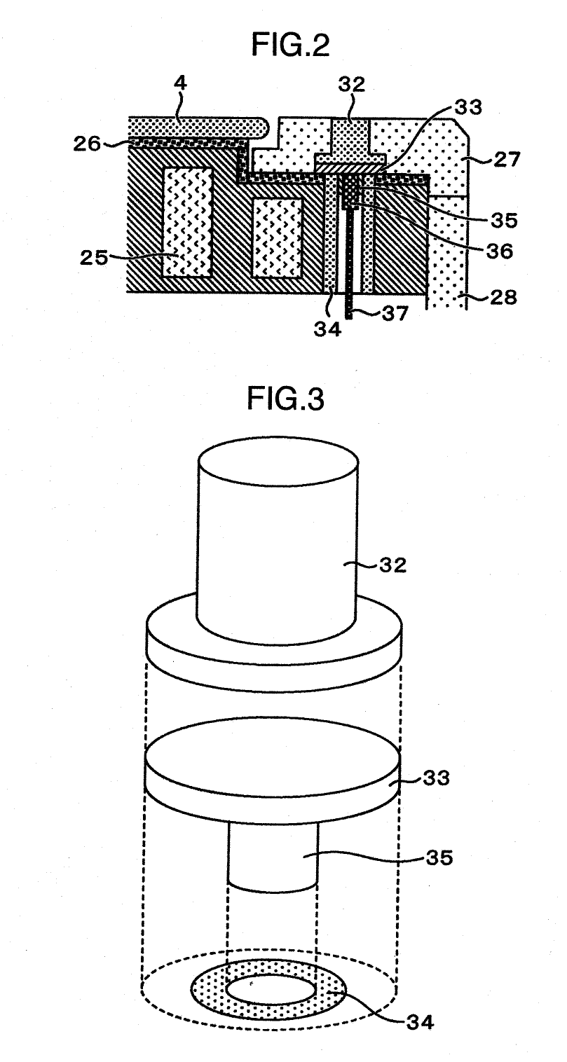

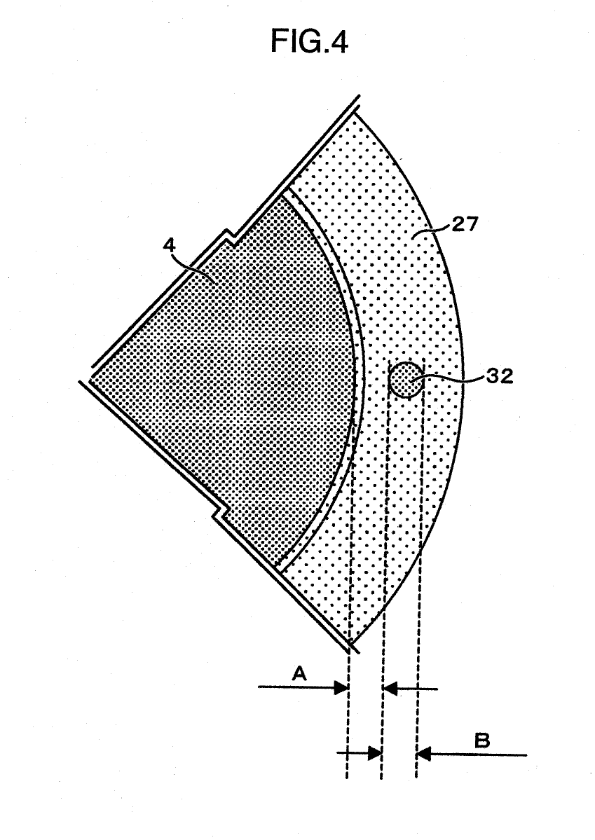

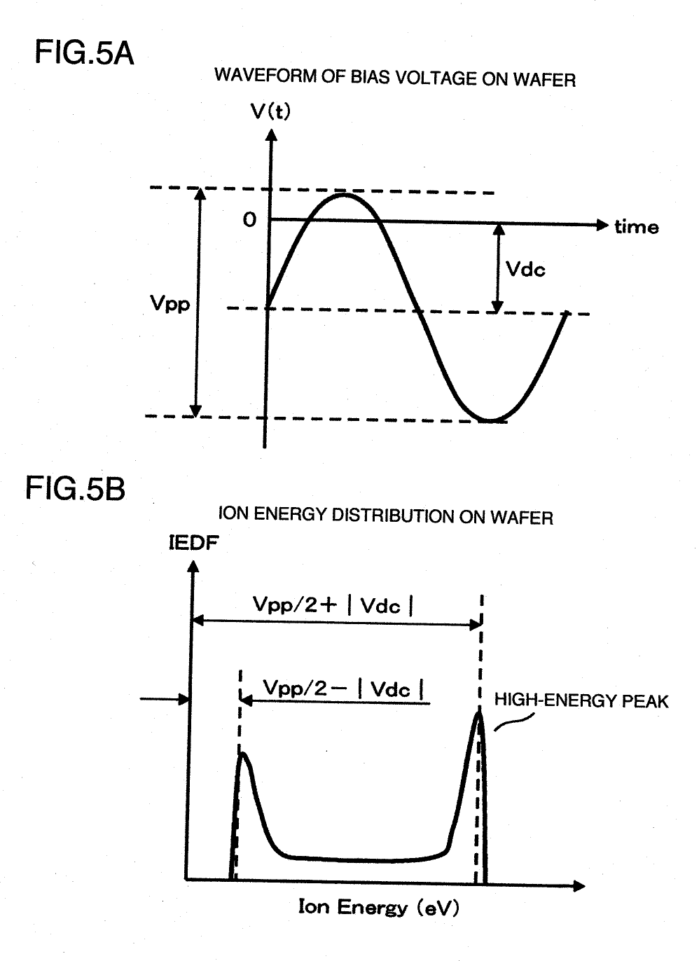

Next, the structure of the voltage detection head 30 is described in detail with reference to FIGS. 2 to 4. FIG. 2 is a sectional view showing the state in which the voltage detection head 30 according to the embodiment shown in FIG. 1 is mounted on the substrate stage 5. It is, specifically, a figure which shows the susceptor 27 shown as a portion of the broken line in FIG. 1 and its peripheral portion enlarged. FIG. 3 is a perspective view schematically showing the outline of the configuration of the voltage detection head 30 shown in FIG. 2. FIG. 4 is a plan view from above of an appearance in which the voltage detection head 30 is disposed inside the susceptor 27.

As shown in FIGS. 2 and 3, the voltage detection head 30 is configured to comprise an upper piece 32 and a lower piece 33 which are replaceable as being divided. A through hole of a diameter of 5 mm to 10 mm is arranged in the step portion arranged in the outer circumferential portion of the mounting surface of the substrate stage 5 and an insulating pipe 34 is inserted into the through hole to electrically insulate the inside from the outside. The lower piece 33 has a large-diameter disc made of metal and has a configuration in which a lower portion of the lower piece 33 is inserted into and retained in an opening in an upper end portion of the insulating pipe 34.

The lower piece 33 has a structure in which a substantially disc-like metal plate of a diameter of 10 mm to 50 mm and of thickness of about 1 mm to about 5 mm is provided and a ring-like or cylinder-like socket 35 is connected to its bottom surface. Also, a plug 36 is put through and retained in the socket 35 to be electrically connected to the metal plate. A lower end portion of the plug 36 is connected to a tip of a signal line 37 and the other end portion of the signal line 37 is connected to an input side of the voltage divider 31.

The upper piece 32 which is attachable/detachable is provided above the lower piece 33. The upper piece 32 is formed as a single piece which has a shape of a disc having a diameter substantially the same as that of the disc portion of the lower piece and a cylinder of a smaller diameter than that of the disc placed on the disc concentrically. The diameter of a top surface of the cylindrical portion of the upper piece 32 is 4 mm to 40 mm.

Since radio frequency power is applied to the upper piece 32 in the same manner as the wafer 4 and a bias potential is formed above, it is worn out by collision with charged particles when it is used for a long time. Therefore, the upper piece 32 has a structure easily attachable/detachable and replaceable. In addition, for a material of the upper piece in the present embodiment a material which is less likely to cause metal contamination to the wafer and high in conductivity, that is silicon doped with boron or phosphor having resistivity of 1 Ωcm or lower. Moreover, by depositing aluminum by sputtering on a bottom surface of the large-diameter disc portion of the upper piece 32 and performing heat treatment thereon, DC electric contact when it is brought into contact with the lower piece 33 can be secured more. Furthermore, a stepped through hole is arranged in the susceptor 27 in accordance with the shape of the state with the upper piece 32 and the lower piece 33 brought into contact with each other so that the upper piece 32 and the lower piece 33 put on each other are fitted to the through hole of the susceptor 27 and retained therein. In this state, the top surface of the cylindrical portion which is the upper portion of the upper piece 32 is made at the same height as the top surface of the susceptor 27.

As shown in FIG. 4, the upper piece 32 must be disposed in a suitable position relative to an outer circumferential edge of the wafer 4; if the upper piece 32 is too close to the outer edge of the wafer 4, however, the etching properties (rate, perpendicularity, etc.) near the edge portion of the wafer 4 may deteriorate due to the influence of the upper piece 32. Also, when the upper piece 32 is too far from the edge of the wafer 4, the plasma conditions on the wafer 4 and the plasma conditions on the upper piece 32 of the voltage detection head 30 may be greatly different and measurement of Vpp and Vdc with high accuracy may become difficult.

In the present embodiment, the upper piece 32 is disposed in a position satisfying the following relation:

0.5×B<A<3.0×B.

Here, A designates a distance from the edge of the wafer 4 to the upper end of the cylindrical portion of the upper portion of the upper piece 32 of the voltage detection head 30 and, in the present embodiment, a distance to the opening on the upper surface communicating with the through hole of the susceptor 27. Also, B designates the diameter of the cylindrical portion of the upper portion of the upper piece 32 of the voltage detection head 30 and, in the present embodiment, is equal to the diameter of the aforementioned opening. That is, in the aforementioned conditions, the horizontal distance between the upper end of the voltage detection head 30 facing the wafer 4 or the plasma and the wafer 4 is set in a range of ½ to 3 times of the diameter of the upper end portion of the voltage detection head 30.

In order to measure Vpp and Vdc of the radio frequency bias accurately using the voltage detection head 30 configured thus, the bias applied to the voltage detection head 30 must be made equivalent to that applied to the wafer 4 in addition that there is no great difference between the plasma density just above the wafer 4 and the plasma density just above the voltage detection head 30.

The wafer 4 is capacitively coupled with the base of the substrate stage 5 through the insulating layer 26. In the current embodiment, where the capacitance is C₁ (pF), the area of the wafer 4 is S₁ (cm²), and the area of the top surface of the voltage detection head is S₂ (cm²), the capacitance C₂ of coupling between the voltage detection head 30 or a portion of its conductive member and the substrate stage 5 or the base serving as an electrode is set as C₂=S₂×C₁/S₁. When C₂ is sufficiently smaller than that value, a radio frequency bias will hardly be applied to the voltage detection head 30. On the contrary, when C₂ is sufficiently greater than that value, a voltage of the bias voltage applied to the wafer 4 or higher will be applied to the voltage detection head 30.

According to the aforementioned embodiment, the waveform of the bias voltage generated on the wafer 4 can be predicted with high accuracy using the result detected by the voltage detection head 30. That is, Vdc generated on the wafer 4 can be detected in-situ simply and easily. By using this detected result to adjust Vpp/2+|Vdc| to be constant to thereby control an ion energy corresponding to a high-energy peak of IEDF to be constant, it is possible to provide a plasma etching apparatus which can provide machining with high precision and stability for a long term in accordance with miniaturization of the next generation.

Incidentally, description up to here is made on an example of a microwave ECR apparatus with a magnetic field as a plasma source; however, the present invention is not limited thereto. As long as a bias is applied to a wafer, for another plasma source, that is of a parallel plate type or an inductively coupled type, the effect of the present invention is unchanged.

It should be further understood by those skilled in the art that although the foregoing description has been made on embodiments of the invention, the invention is not limited thereto and various changes and modifications may be made without departing from the spirit of the invention and the scope of the appended claims.

1. A plasma processing apparatus comprising:
a processing chamber which is disposed in a vacuum vessel and within which plasma is formed;
a stage which is disposed in the processing chamber and on a mounting surface of a top portion of which a wafer to be processed can be mounted;
a power supply which supplies radio frequency power to an electrode disposed in the stage so as to form a bias potential, the radio frequency power being supplied from the power supply during processing of the wafer using the plasma;
a detector which is disposed on an outer circumferential side of the mounting surface of the stage to detect a differential component Vpp between a maximum value and a minimum value and a DC component Vdc from a value of the bias voltage formed thereabove; and
a controller which adjusts an output of radio frequency bias power to make a value of Vpp/2+|Vdc| constant during the processing based on an output from the detector.

2. The plasma processing apparatus according to claim 1, wherein a top end of the detector is made at substantially a same height as a top surface of the wafer or a top surface of the wafer when it is mounted thereon and facing the plasma, and wherein electrostatic coupling capacitance per unit area between the stage and the detector is made equal to electrostatic coupling capacitance per unit area between the stage and the wafer.

3. The plasma processing apparatus according to claim 2, wherein a distance between a portion of the detector facing the plasma and an outer circumferential edge of the wafer is set within a range of ½ to 3 times the portion facing the plasma when the wafer is mounted and retained on the mounting surface.

4. The plasma processing apparatus according to claim 1, wherein a distance between a portion of the detector facing the plasma and an outer circumferential edge of the wafer is set within a range of ½ to 3 times the portion facing the plasma when the wafer is mounted and retained on the mounting surface.

5. A plasma processing method comprising the steps of:
mounting a wafer to be processed on a mounting surface of a top portion of a stage disposed in a processing chamber in a vacuum vessel;
forming plasma in the processing chamber;
supplying radio frequency power for forming a bias potential, from a power supply electrically connected to an electrode disposed in the stage to perform processing on the wafer using the plasma; and
adjusting an output of radio frequency bias power to make a value of Vpp/2+|Vdc| constant during the processing, based on an output of a detector which is disposed on an outer circumferential side of the mounting surface of the stage to detect a differential component Vpp between a maximum value and a minimum value and a DC component Vdc from a value of the bias voltage formed thereabove.

6. The plasma processing method according to claim 5, wherein a top end of the detector is made at substantially a same height as a top surface of the wafer or a top surface of the wafer when it is mounted thereon and facing the plasma, and wherein electrostatic coupling capacitance per unit area between the stage and the detector is made equal to electrostatic coupling capacitance per unit area between the stage and the wafer.

7. The plasma processing method according to claim 6, wherein a distance between a portion of the detector facing the plasma and an outer circumferential edge of the wafer is set within a range of ½ to 3 times the portion facing the plasma when the wafer is mounted and retained on the mounting surface.

8. The plasma processing method according to claim 5, wherein a distance between a portion of the detector facing the plasma and an outer circumferential edge of the wafer is set within a range of ½ to 3 times the portion facing the plasma when the wafer is mounted and retained on the mounting surface.
